(19) United States
(12) Patent Application Publication
(10) Pub. No.: US 2020/0161445 A1
(43) Pub. Date: May 21, 2020

(54) SEMICONDUCTOR DEVICE AND METHOD OF MANUFACTURING THE SAME

(71) Applicant: RENESAS ELECTRONICS CORPORATION, Tokyo (JP)

(72) Inventors: Hironobu MIYAMOTO, Ibaraki (JP); Yasuhiro OKAMOTO, Ibaraki (JP); Kenichi HISADA, Ibaraki (JP); Koichi ARAI, Ibaraki (JP); Nobuo MACHIDA, Ibaraki (JP)

(21) Appl. No.: 16/597,600

(22) Filed: Oct. 9, 2019

(30) Foreign Application Priority Data
Nov. 15, 2018 (JP) 2018-214291

(51) Int. Cl. H01L 29/66; H01L 29/16; H01L 29/36; H01L 29/417

(52) U.S. Cl. CPC H01L 29/66136; H01L 29/4175; H01L 29/36; H01L 29/1608

(57) ABSTRACT

An n-type epitaxial layer is formed on an n-type semiconductor substrate made of silicon carbide. p-type body regions are formed in the epitaxial layer, and n-type source region is formed in the body region. On the body region between the source region and the epitaxial layer, a gate electrode is formed via a gate dielectric film, and an interlayer insulating film having an opening is formed so as to cover the gate electrode. A source electrode electrically connected to the source region and the body regions is formed in the opening. A recombination layer is formed between the body region and a basal plane dislocation is a layer having point defect density higher than that of the epitaxial layer located directly under the recombination layer or having a metal added to the epitaxial layer.

### CROSS-REFERENCE TO RELATED APPLICATIONS

The disclosure of Japanese Patent Application No. 2018-214291 filed on Nov. 15, 2018 including the specification, drawings and abstract is incorporated herein by reference in its entirety.

### BACKGROUND

The disclosed embodiments relate to semiconductor device and method of manufacturing the same, particularly, it relates to semiconductor device using a silicon carbide substrate.

Silicon carbide (SiC) has a wide band gap, and the maximum insulated electric field is about greater by 10 times than that of silicon (Si), so SiC has been attracted as a material of a power device replacing Si. In power devices using SiC substrate, not only a pn-type body diode but also a Schottky Barrier Diode (SBD) may be incorporated in a semiconductor chip in order to reduce on-resistance.

For example, a power device using a SiC substrate embedded a pn-type body diode and a Schottky barrier diode is disclosed in Japanese Patent Laid-Open No. JP-A-2007-234925 (Patent Document 1) and in K. Kawahara et al., “Impact of Embedding Schottky Barrier Diode into 3.3 kV and 6.5 kV SiC MOSFETs”, ICSCRM2017 TU.D2.8 (Non-patent Document 1).

### SUMMARY

In power devices using a SiC substrate, it is common practice to form an epitaxial layer as a drift layer on the SiC substrate. Various types of defects are formed in the epitaxial layer made of SiC, and many of the defects are propagated from the SiC substrate which is a bulk substrate. Since the epitaxial layer is formed on a plane inclined by several degrees (for example, 5 degrees) with respect to a ground plane by an epitaxial growth method, a Basal Plane Dislocation (BPD) which is a linear crystalline defect included in a (0001) ground plane grows from the SiC substrate toward a surface of the epitaxial layer in accordance with recombination energies of electrons and holes. In addition, it is known that, when the BPD grows, Shockley type stacking defects are formed in the epitaxial layer, and the Shockley type stacking defects are accelerated by recombination of electrons and holes.

In this case, in a Metal Insulator Semiconductor Field Effect Transistor (MISFET) using the SiC substrate, when a current flows through a pn-type body diode, holes injected from a p-type layer and electrons injected from the SiC substrate recombine in the BPD, thereby expanding the Shockley type stacking defects and increasing a resistivity of a SiC crystal. There is a problem that a performance of the semiconductor device is deteriorated.

Other objects and novel features will become apparent from the description of this specification and the accompanying drawings.

The typical ones of the embodiments disclosed in the present application will be briefly described as follows.

A semiconductor device according to an embodiment includes a semiconductor substrate of a first conductivity type made of silicon carbide and having a upper surface and a back surface, a semiconductor layer of a first conductivity type formed on the upper surface of the semiconductor substrate, a first impurity region of a second conductivity type opposed to the first conductivity type formed in the semiconductor layer, and a second impurity region of a first conductivity type formed in the first impurity region and having an impurity density higher than that of the semiconductor layer. In addition, the semiconductor device includes gate electrode formed on the first impurity region between the second impurity region and the semiconductor layer with the gate dielectric film interposed therebetween, and an interlayer insulating film formed to cover the gate electrode and having an opening for opening a portion of the first impurity region and a portion of the second impurity region. The semiconductor device has a source electrode formed on the interlayer insulating film and electrically connected to the first impurity region and the second impurity region in the opening, and a drain electrode formed on the back surface of the semiconductor substrate. Wherein, a recombination layer is formed in the semiconductor layer under the first impurity region, and the recombination layer is a layer having point defect density higher than that of the semiconductor layer located directly under the recombination layer or having a metal added to the semiconductor layer.

According to the embodiments, it is possible to improve a performance of a semiconductor device.

### BRIEF DESCRIPTION OF THE DRAWINGS

FIG. 1 is a main portion cross-sectional view of a semiconductor device of a first embodiment.

FIG. 2 is a main portion cross-sectional view of a semiconductor device of examination example.

FIG. 3 is a graph illustrated calculation results by the inventors.

FIG. 4 is a main portion cross-sectional view of the semiconductor device of the first embodiment.

FIG. 5 is a graph illustrated calculation results by the inventors.

FIG. 6 is a graph illustrated calculation results by the inventors.

FIG. 7 is a cross-sectional view illustrated a manufacturing step of the semiconductor device in the first embodiment.

FIG. 8 is a cross-sectional view illustrated a manufacturing step following FIG. 7.

FIG. 9 is a cross-sectional view illustrated a manufacturing step following FIG. 8.

FIG. 10 is a cross-sectional view illustrated a manufacturing step following FIG. 9.

FIG. 11 is a cross-sectional view illustrated a manufacturing step following FIG. 10.

FIG. 12 is a cross-sectional view illustrated a manufacturing step following FIG. 11.

FIG. 13 is a cross-sectional view illustrated a manufacturing step following FIG. 12.

FIG. 14 is a cross-sectional view illustrated a manufacturing step following FIG. 13.

FIG. 15 is a cross-sectional view illustrated a manufacturing step following FIG. 14.

FIG. 16 is a cross-sectional view illustrated a manufacturing step following FIG. 15.

FIG. 17 is a cross-sectional view illustrated a manufacturing step following FIG. 16.

FIG. 18 is a cross-sectional view illustrated a manufacturing step following FIG. 17.

FIG. 19 is a cross-sectional view illustrated a manufacturing step following FIG. 18.

FIG. 20 is a main portion cross-sectional view of a semiconductor device of a second embodiment.

FIG. 21 is a cross-sectional view illustrated a manufacturing step of the semiconductor device in the second embodiment.

FIG. 22 is a cross-sectional view illustrated a manufacturing step following FIG. 21.

FIG. 23 is a cross-sectional view illustrated a manufacturing step following FIG. 22.

FIG. 24 is a cross-sectional view illustrated a manufacturing step following FIG. 23.

FIG. 25 is a cross-sectional view illustrated a manufacturing step following FIG. 24.

FIG. 26 is a cross-sectional view illustrated a manufacturing step following FIG. 25.

FIG. 27 is a cross-sectional view illustrated a manufacturing step following FIG. 26.

FIG. 28 is a cross-sectional view illustrated a manufacturing step following FIG. 27.

FIG. 29 is a cross-sectional view illustrated a manufacturing step following FIG. 28.

FIG. 30 is a cross-sectional view illustrated a manufacturing step following FIG. 29.

FIG. 31 is a cross-sectional view illustrated a manufacturing step following FIG. 30.

FIG. 32 is a main portion cross-sectional view of a semiconductor device of a third embodiment.

FIG. 33 is a cross-sectional view illustrated a manufacturing step of the semiconductor device in the third embodiment.

### DETAILED DESCRIPTION

In the following embodiments, when required for convenience, the description will be made by dividing into a plurality of sections or embodiments, but except when specifically stated, they are not independent of each other, and one is related to modifications, detail, supplementary description, or the like of part or all of the other. In the following embodiments, reference to the number of elements or the like (including the number, numerical value, quantity, range, and the like) is not limited to the specific number, and may be greater than or equal to the specific number or less, except in the case where it is specifically specified and the case where it is obviously limited to the specific number in principle. Furthermore, in the following embodiments, it is needless to say that the constituent elements (including the element steps and the like) are not necessarily essential except in the case where they are specifically specified and the case where they are considered to be obviously essential in principle. Similarly, in the following embodiments, reference to shapes, positional relationships, and the like of constituent elements and the like includes substantially approximate or similar shapes and the like, except for the case in which they are specifically specified and the case in which they are considered to be obvious in principle and the like. The same applies to the above numerical values and ranges.

Hereinafter, embodiments will be described in detail based on the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, in cross-sectional view and plan view, the sizes of the respective parts do not correspond to actual devices, and certain parts may be displayed relatively large in order to make the drawing easy to understand. In addition, even when the cross-sectional view corresponds to the plan view, a particular portion may be displayed relatively large in order to make the drawing easier to understand.

In the drawings used in the embodiments, hatching may be omitted in order to make the drawings easier to see.

In the following embodiment, when expressing “B positioned directly under A” or the like, the relationship between A and B includes the case where they are in direct contact with each other and the case where there are other components between them. In other words, the relationship between A and B means that they overlap in plan view. The same relationship holds when expressing “directly above” instead of “directly under”.

### First Embodiment

<Structure Semiconductor Device>

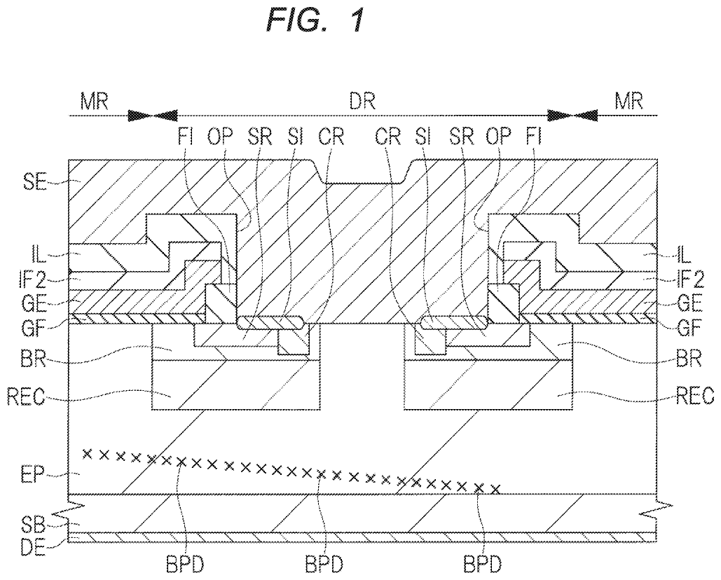

FIG. 1 is a main portion cross-sectional view of a semiconductor chip that is a semiconductor device of a first embodiment, and the semiconductor chip includes a MISFET region MR in which an n-type MISFET is formed and a diode region DR in which a pn-type diode and a Schottky Barrier Diode (SBD) are formed.

A semiconductor substrate SB used in the first embodiment is a compound semiconductor substrate containing carbon and silicon, specifically, it is a silicon carbide (SiC) substrate into which an n-type impurity such as nitrogen (N) is introduced. An impurity concentration of the semiconductor substrate SB is, for example, 1×10¹⁹/cm³. The semiconductor substrate SB has a upper surface and a back surface which is a surface opposed to the upper surface, and a drain electrode DE formed of a conductive film in which, for example, an aluminum (Al) film and a gold (Au) film are laminated as a back surface electrode is formed on the back surface of the semiconductor substrate SB.

An epitaxial layer (semiconductor layer) EP introduced with n-type impurity is formed on the semiconductor substrate SB. A thickness of the epitaxial layer EP is, for example, 10 μm, and an impurity concentration of the epitaxial layer EP depends on a rating breakdown voltage of the device, wherein, for example, it is 1×10¹⁶/cm³. The epitaxial layer EP is a drifting layer of the semiconductor device of the first embodiment, and it is a path for a current flowing vertically in the MISFET region MR. In a region near a surface of the epitaxial layer EP, body regions (impurity regions) BR introduced with p-type impurity such as aluminum is formed in the epitaxial layer EP, and source regions (impurity regions) SR introduced with p-type impurity such as nitrogen is formed in the body regions BR. The source regions SR constitutes a source region of the MISFET, and the epitaxial layer EP constitutes a drain region of the MISFET. In the body regions BR, a region sandwiched between the source regions SR and the epitaxial layer EP becomes a channel region of the MISFET.

And, a p-type impurity such as aluminum is introduced into the body regions BR, and a contact regions CR having an impurity concentration higher than that of the body regions BR are formed. The contact regions CR are mainly provided to reduce a contact resistance between the body regions BR and the source electrode SE and to fix the body regions BR in a predetermined potential (source potential).

A thickness of the body regions BR, that is, a depth of the epitaxial layer EP from an upper surface is, for example, 0.4 μm, and the body regions BR does not reach a lower surface of the epitaxial layer EP. A thickness of the source regions SR is, for example, 0.15 μm, which is smaller than the thickness of the body regions BR. A thickness of the contact regions CR is, for example, 0.2 μm, and is smaller than or equal to the thickness of the body regions BR.

On the source regions SR, for example, a field insulating film (element isolation film) FI having a thickness of, for example, 250 nm is formed. As described later, the field insulating film FI is a laminated film of an insulating film IF1 which is a silicon oxide film and another silicon oxide film formed by oxidizing a polycrystalline silicon film PS1. However, in the first embodiment, this laminated film is illustrated as a single-layer field insulating film FI for simplification of an explanation.

A gate dielectric film GF of MISFET is formed on the body regions BR to be a channel region, and MISFET gate electrode GE is formed on the gate dielectric film GF. And, an insulating film IF2 is formed as a capping film on the gate electrode GE. The gate dielectric film GF and the gate electrode GE is also formed above a portion of the source regions SR and a portion of the epitaxial layer EP. One end of the gate electrode GE is located on the field insulating film FI, and another end of the gate electrode GE is located on the epitaxial layer EP via the gate dielectric film GF. A portion of the body regions BR below the gate electrode GE to be a channel region during an operation of the MISFET.

The gate dielectric film GF is an insulating film such as a silicon oxide film, and has a thickness of, for example, 50 nm. The gate electrode GE is a conductive film, for example, a polycrystalline silicon film introduced with n-type impurity such as phosphorus (P), and has a thickness of, for example, 200 nm. The insulating film IF2 is, for example, an insulating film such as a silicon nitride film, and has a thickness of, for example, 150 nm.

An interlayer insulating film IL is formed on the epitaxial layer EP so as to cover the MISFET including the gate electrode GE and the like. The interlayer insulating film IL is, for example, an insulating film such as a silicon oxide film, and has a thickness of, for example, 250 nm. In the interlayer insulating film IL, an opening (contact hole) OP for opening a portion of each the body regions BR, the contact regions CR and the source regions SR are formed.

In the opening OP, a silicide layer SI is formed on the source regions SR and the contact regions CR. The silicide layer SI is, for example, made of nickel silicide.

A source electrode SE which is electrically connected to the source regions SR and the contact regions CR are formed on the interlayer insulating film IL so as to embed an inside of the opening OP. That is, the source electrode SE is connected to the source regions SR via the silicide layer SI and is connected to the body regions BR via the contact regions CR and the silicide layer SI. Thus, the source electrode SE is connected to the source regions SR and the contact regions CR in ohmic connection, and a source potential is supplied from the source electrode SE to the source regions SR and the body regions BR.

The source electrode SE has a barrier metal film and a conductive film formed on the barrier metal film. The barrier metal film is a titanium (Ti) film, a titanium nitride (TiN) film or a laminated film in which a titanium nitride film is formed on a titanium film, and the conductive film is an aluminum film.

And, the opening OP also opens a region of the epitaxial layer EP, where the body regions BR are not formed. That is, although two body regions BR are illustrated in FIG. 1, the epitaxial layer EP between the two body regions BR is exposed in the opening OP. The source electrode SE is directly connected to the epitaxial layer EP in the opening OP, and the source electrode SE and the epitaxial layer EP are Schottky connected. That is, the SBD is formed in the opening OP.

And, the body regions BR and the epitaxial layer EP constitute a pn-type diode as a body diode. That is, the SBD and the pn-type diode are formed in the diode region DR.

As main feature of the first embodiment, a recombination layer REC is formed in the epitaxial layer EP below the body regions BR. By providing such the recombination layer REC, holes flowing from the body regions BR and electrons flowing from the semiconductor substrate SB are combined in the recombination layer REC during the operation of the pn-type diode, so that the stacking defects can be suppressed from increasing in the BPD existing in the epitaxial layer EP. As a result, since an on-resistance of the MISFET can be suppressed from increasing, the performance of the semiconductor device can be improved.

Hereinafter, the features of the first embodiment will be described in detail by using a semiconductor device of an examination example discussed by the inventors.

<Semiconductor Device of an Examination Example and their Problems>

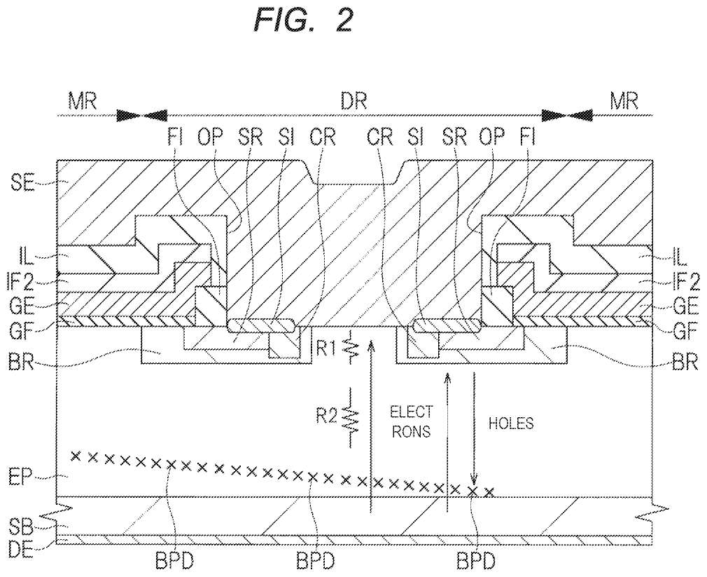

FIG. 2 shows a main portion cross-sectional view of a semiconductor chip which is a semiconductor device of an examination example. Although FIG. 2 is a cross-sectional view, some hatching is omitted in FIG. 2 in order to easy to see an illustration of resistive components R1, R2 and the like. In the following explanation, differences from first embodiment will be mainly explained, and explanation of portions overlapping with the first embodiment will be omitted.

As shown in FIG. 2, the semiconductor device of the examination example includes a MISFET, an SBD and a pn-type diode which is a body diode similarly to the first embodiment. However, in the examination example, unlike the first embodiment, the recombination layer REC is not formed below the body regions BR.

As described above, as a problem of a device using semiconductor substrate SB made of SiC, it is known that stacking defects grow, and on-resistance increases when holes and electrons recombine in the BPD. For example, when voltage is applied in opposite direction to source and drain in the MISFET, the pn-type diode, which is the body diode of an inverter circuit, becomes conductive, and electrons and holes shown in FIG. 2 can be flow. When these holes are injected into the BPD, the above problem occurs.

As a method for preventing such a problem, holes are prevented from being injected into the BPD during the operation of the pn-type diode by embedded an SBD in the semiconductor chip so as to be connected in parallel with the pn-type diode. That is, the semiconductor chip with the embedded SBD has a structure in which the pn-type diode is not turned on.

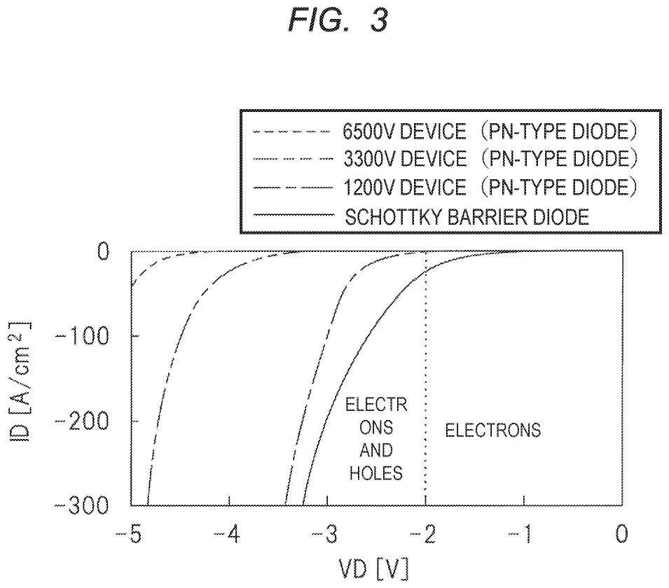

FIG. 3 is a graph illustrated results calculated by the inventors for characteristics of a drain current (ID) and a drain-source voltage (VD) of the pn-type diode and the SBD. FIG. 3 shows the characteristics of each pn-type diode for products with rated withstand voltages of 6500 V, 3300 V, and 1200 V required for the semiconductor chip.

For the 6500V product and the 3300V product, a state in which the pn-type diode is not turned on can be maintained by the embedded SBD in the semiconductor chip. However, for 1200V product, it has been found that the operation voltage of the pn-type diode may be lowered, and the pn-type diode may be turned on.

The 1200V product has a thinner drift layer (epitaxial layer EP) and a smaller resistance component (R2) than the 6500V product and the 3300V product. Therefore, a voltage value VD·R 1/(R1+R2) applied to a pn-junction between the body regions BR and the epitaxial layer EP becomes large. Therefore, when a current having a rated current of 300 A/cm² is supplied to the transistor, holes are injected into the BPD because the pn-type diode is turned on, and stacking defects are increased. That is, the inventors have investigated that while the SBD can be suppressed from increasing in the stacking defects in the product high withstand voltage 1200 V by embedded the SBD in the semiconductor chip, in the 1200V product, the embedding of the SBD in the semiconductor chip is not enough to suppress the increase in the stacking defects.

<Main Features of the Semiconductor Device of the First Embodiment>

The semiconductor device of the first embodiment was devised considering of the problem of the examination example. As described above, main features of the semiconductor device of the present embodiment is that the recombination layer REC is formed in the epitaxial layer EP under the body regions BR. The recombination layer REC has a higher point defect density and a higher sheet resistance than the epitaxial layer EP located directly under the recombination layer REC. The recombination layer REC is a layer formed inside the epitaxial layer EP, and is formed at a position not reaching the lower surface of the epitaxial layer EP. The recombination layer REC is formed on the BPD existing in the epitaxial layer EP. Also, the recombination layer REC may be in contact with the body regions BR, but the recombination layer REC may be spaced apart from the body regions BR such that a thin epitaxial layer EP exists between the body regions BR and the recombination layer REC. That is, it is important that the recombination layer REC is provided between the body regions BR and the BPD.

By providing such the recombination layer REC, holes flowing from the body regions BR and electrons flowing from the semiconductor substrate SB are combined in the recombination layer REC during the operation of the pn-type diode that holes flowing from the body regions BR hardly reach the BPD. When stacking defects increase in the BPD, a layer of high resistance is formed in the drift layer (epitaxial layer EP) through which current flows. As a result, the on-resistance of the MISFET increases.

In the first embodiment, the recombination layer REC is selectively provided below the body regions BR, and the high-resistance recombination layer REC is not provided in the MISFET current path and the SBD current path. Therefore, it is possible to suppress an increase in the on-resistance. Thus, by selectively providing the recombination layer REC in the current paths of the pn-type diode, it is possible to suppress an increase in stacking defects in the BPD, thereby suppressing the problem of an increase in the on-resistance of the MISFET and improving the performance of the semiconductor device.

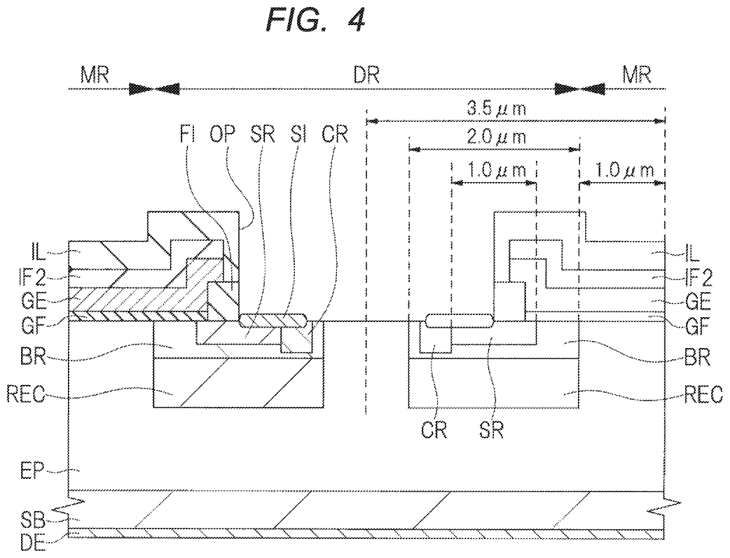

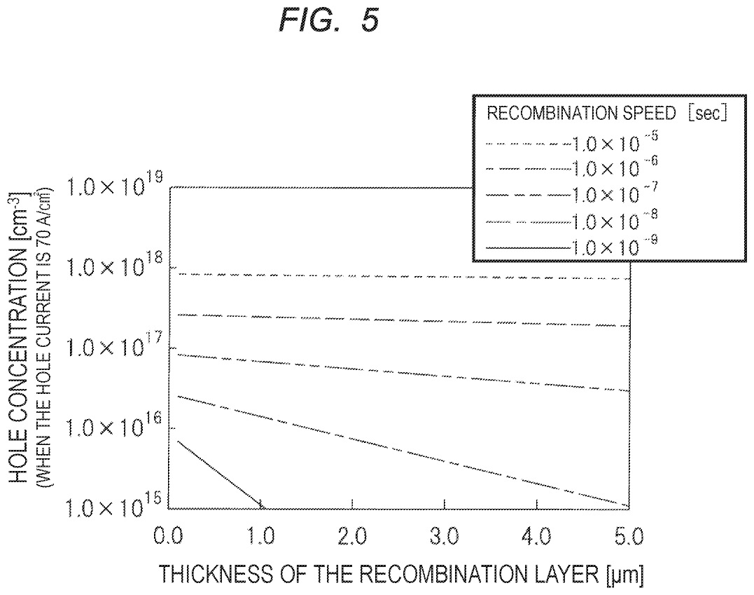

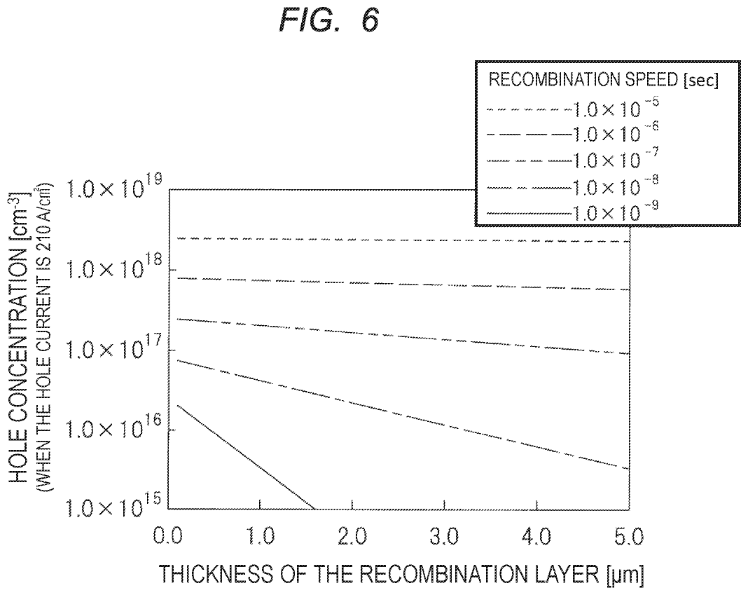

Hereinafter, a relationship between holes coupled in the recombination layer REC and stacking defects generated in the BPD will be described with reference to FIGS. 4 and 5. FIG. 4 is a similar cross-sectional view as FIG. 1, but it shows the dimensions of the respective components. Therefore, in FIG. 4, the source electrode SE is not shown, and some hatching and reference numerals are also omitted. FIG. 5 is a graph illustrated results of calculation by the inventors regarding a relationship between a concentration of holes injected into the recombination layer REC and a thickness of the recombination layer REC. FIG. 6 is a graphical representation of the same purposes as FIG. 5, but it relates to the second embodiment described later.

When the MISFET standardized by an area based on a dimension entered in FIG. 4 is used in inverters at a rated drain current density of 300 A/cm², the pn-type diode has a current density of 300 A/cm² may flow. In a unit cell composed of the MISFET and the SBD in the first embodiment, a ratio of an area occupied by a diode region DR is 5/7. Therefore, if standardized by an area of only diode region DR, it is calculated that a current having a current density of 420 A/cm² flows in the diode region DR.

In the case of a MISFET having an embedded SBD and a rated withstand voltage of 1200 V as in first embodiment, as shown in FIG. 3, of the current of the entire diode region DR, a current of about ⅔ flows in the SBD, and a current of about ⅓ flows in the pn diode. Assuming that ½ of the current of the pn-type diode is a hole current, it can be estimated that a hole current of 70 A/cm² flows and holes are injected into the n-type epitaxial layer EP.

Wherein, the hole current component flowing through the pn-type diode is expressed by the following equation (1), and the hole concentration can be expressed by the following equation (2).

Iₕ=q·Dₕ·pₙ/sgrt(Dₕ·tₚ), Dₕ=k·T·uₕ/q (1)

p(x)=(pₙ−pₙ₀)exp(−x/(Dₕ−tₚ))+pₙ₀ (2)

Wherein, Iₕ is a hole current, q is the unit of charge, Dₕ is the diffusion coefficient of hole, pₙ is a hole concentration on a n-layer side at a pₙ-interface, pₙ₀ is a hole concentration in the n-layer at thermal equilibrium, tₚ is a recombination speed of holes, k is the Boltzmann constant, T is a temperature, uₕ is the hole mobility, and x is a distance from the pₙ-interface.

FIG. 5 shows a depth distributions of hole concentrations when a hole current of 70 A/cm² flows into the recombination layer REC by using a hole recombination speed as a parameter.

Assuming that the recombination speed of holes in the epitaxial layer EP is 1 μsec, holes of the order of 1×10¹⁷/cm³ diffuse to a deep position of the drift layer and recombine at the BPD. Therefore, the recombination layer REC having a hole recombination speed of 10 nsec is inserted into the epitaxial layer EP above the BPD and setting a thickness of the recombination layer REC to 1.5 μm or more, a hole concentration passing through the recombination layer REC is reduced to 1×10¹⁶/cm³ or less. Since the concentration of holes injected into the epitaxial layer EP is low, stacking defects caused by hole recombination hardly occur in the BPD.

That is, wherein, the impurity concentration of the epitaxial layer EP is 1×10¹⁶/cm³, and by setting the hole concentration to be equal to or less than the impurity concentration of the epitaxial layer EP, the recombination of holes in the BPD can be suppressed.

<A Method of Manufacturing a Semiconductor Device>

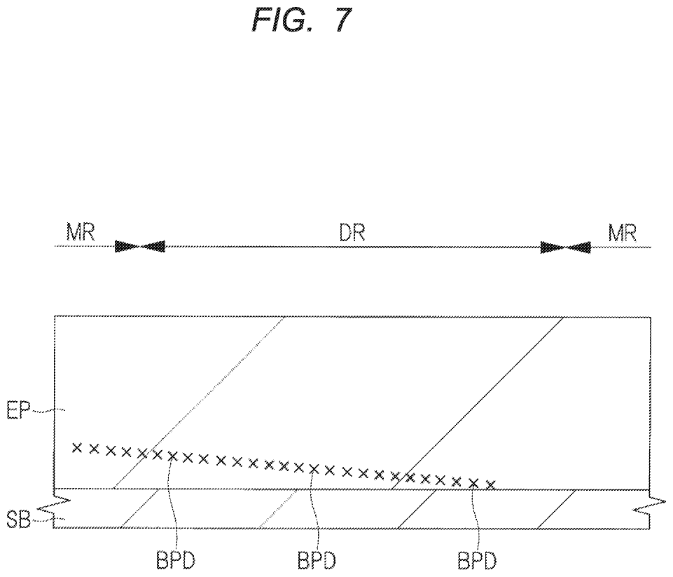

A method of a manufacturing the semiconductor device according to the first embodiment will be described below by using FIGS. 7 to 19. Note that the description of parameters already described, such as the impurity concentration and thickness of each configuration, will be omitted.

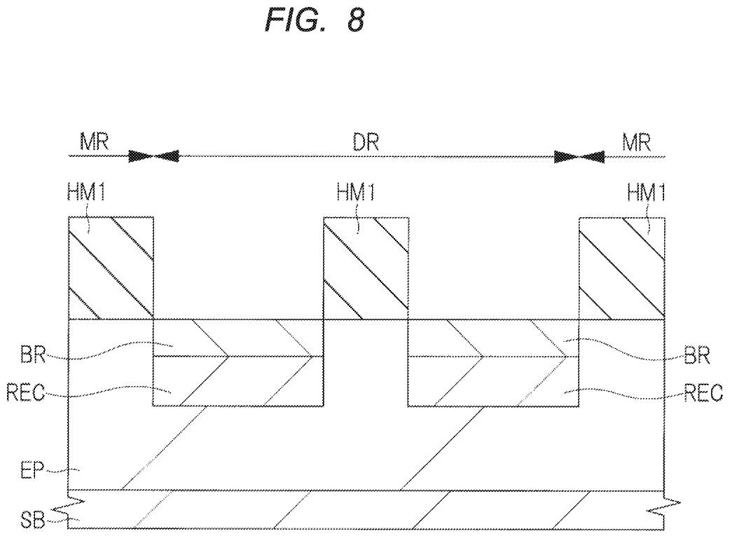

FIG. 7 shows a step of preparing a semiconductor substrate SB on which an epitaxial layer EP is formed. In FIG. 7, a BPD is illustrated, but the BPD is not illustrated in the drawings after FIG. 8 in order to make the drawing easier to see.

First, the semiconductor substrate SB having an upper surface and a back surface, which is a surface opposed to the upper surface, is prepared. Semiconductor substrate SB is a compound semiconductor substrate of carbon and silicon, and more specifically, it is a silicon carbide (SiC) substrate into which an n-type impurity is introduced.

Next, an epitaxial layer EP is formed on the upper surface of the semiconductor substrate SB inclined by 5 degrees with respect to a base surface by an epitaxial growth method. In order to make the epitaxial layer EP n-type, it can be achieved by introducing, for example, a nitrogen (N2) gas into gases used in the epitaxial growth method, and an impurity concentration of the epitaxial layer EP can be set to a desired concentration by adjusting a quantity of nitrogen to be introduced.

FIG. 8 shows a step of forming a plurality of a hard mask HM1, body regions BR, and a recombination layer REC.

First, an insulating film such as a Tetra Ethyl Ortho Silicate (TEOS) film as a silicon oxide film is formed on the epitaxial layer EP by using, for example, Chemical Vapor Deposition (CVD) method. Next, the insulating film is patterned by photolithography technology and etching process to selectively form the plurality of the hard mask HM1 on the epitaxial layer EP. Next, aluminum ions are implanted using the plurality of the hard mask HM1 as mask to form p-type body regions BR in the epitaxial layer EP. Wherein, the plurality of the hard mask HM1 are left without being removed.

Next, using the plurality of the hard mask HM1 as mask, for example, hydrogen (H) ions are implanted to form the recombination layer REC under the body regions BR. The ion implantation is performed in a plurality of times, the acceleration energy is in a range of 100 to 400 keV, and a total dose amount is 2×10¹⁶/cm². In the first embodiment, a thickness of the recombination layer REC is between 1.5 and 2.0 μm. The recombination layer REC may be provided between the body regions BR and a BPD, and may be in contact with the body regions BR or may be separated from the body regions BR.

As described above, since the same plurality of the hard mask HM1 are used in the process of forming the body regions BR and the recombination layer REC, it is unnecessary to manufacture a new mask, and the manufacturing step can be simplified.

Note that the injected hydrogen diffuses in each manufacturing step described later, and finally, a portion where the hydrogen is injected exists as point defects. In addition, since the recombination layer REC is formed at a deep position of the epitaxial layer EP by ion implantation, it is preferable to use an element having a light mass for ion implantation. As such the element, helium (He) can be used instead of hydrogen.

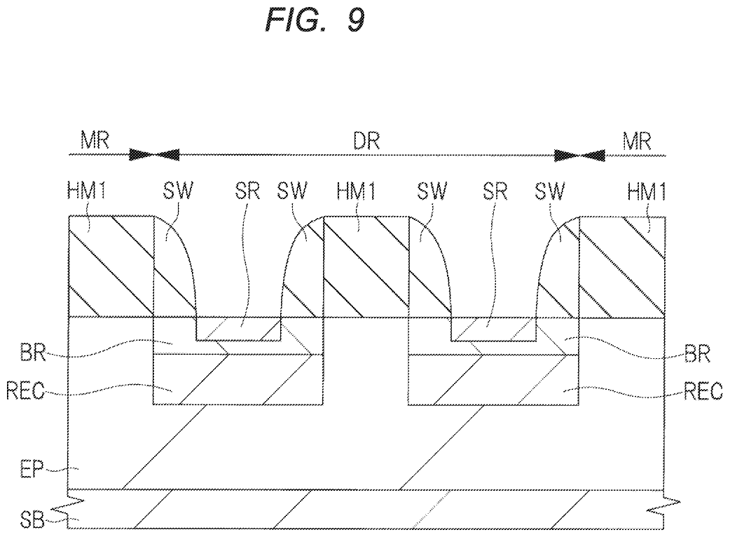

FIG. 9 shows a step of forming sidewall spacers SW and source regions SR.

First, for example, a silicon oxide film is formed on the body regions BR by, for example, a CVD method so as to cover the plurality of the hard mask HM1. Next, the silicon oxide film is performed by anisotropic etching to form the silicon oxide film into a spacer shape, thereby forming sidewall spacers SW on the respective side surfaces of the plurality of the hard mask HM1.

In the anisotropic etching, for example, dry etching is used, but it is considered that an upper surface of the body regions BR exposed to the dry etching is damaged by the dry etching. However, since the body regions BR exposed to the dry etching is a region in which the MISFET source regions SR are formed and is not a region in which the MISFET channel region and the SBD is formed, the use of the dry etching does not matter particularly from a viewpoint of a performance degradation of the MISFET and the SBD.

Next, for example, nitrogen ions are implanted using the plurality of the hard mask HM1 and the sidewall spacers SW formed on the side surfaces of the plurality of the hard mask as mask to form n-type source region SR in the each of body regions BR. The source region SR are formed in the central portion of the body regions BR and are formed so as to be included in the body regions BR in plan view. That is, in an interval between two body region BR adjacent to each other, an epitaxial layer EP in which the body regions BR and the source regions SR are not formed are existed, and body regions BR having a width of about 0.5 μm exists between the epitaxial layer EP and the source regions SR.

Thereafter, the plurality of the hard mask HM1 and the sidewall spacers SW formed on the side surfaces of the plurality of the hard mask HM1 are removed by using a wet etching. wherein, since an upper surface of the epitaxial layer EP between two body region BR adjacent to each other becomes a region in which SBD is to be formed in a later step, it is preferable to reduce damage on the upper surface of the epitaxial layer EP by etching in order to perform good Schottky connection. Therefore, it is preferable to use the wet etching to remove the plurality of the hard mask HM1 and the sidewall spacers SW.

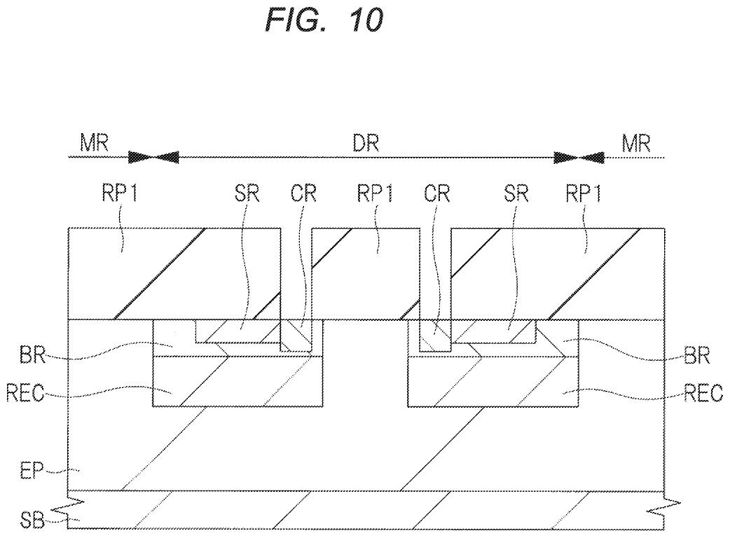

FIG. 10 shows a step of forming contact regions CR.

First, a resist pattern RP1 is formed to selectively open a portion of the body regions BR. Next, ion implantation of aluminum is performed using the resist pattern RP1 as a mask to form a p-type contact regions CR in the body regions BR. The each of contact regions CR are formed at a position in contact with the source regions SR so as to be included in the body regions BR in plan view. Thereafter, the resist pattern RP1 is removed by asking or the like.

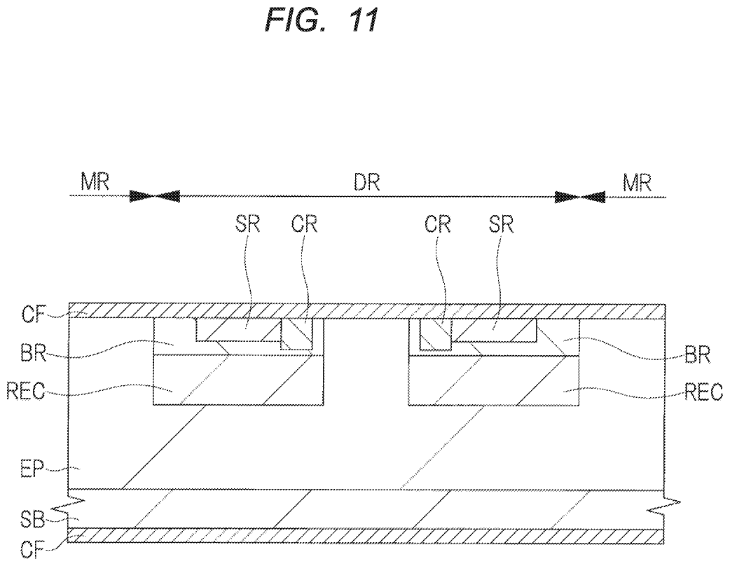

FIG. 11 shows a heat treatment step for each impurity region.

First, a carbon (C) film CF is formed so as to cover an upper surface of the epitaxial layer EP and a back surface of the semiconductor substrate SB. Next, for example, a heat treatment at 1700 to 1800° C. performs to the epitaxial layer EP and the semiconductor substrate SB to activate impurities included in the semiconductor substrate SB, the epitaxial layer EP, the body regions BR, the source regions SR and the contact regions CR. Since the heat treatment is a relatively high temperature and a temperature exceeding the melting point of silicon, it is preferable that the heat treatment performs before forming the gate electrode GE formed of a polycrystalline silicon film or the like. Thereafter, the carbon film CF is removed.

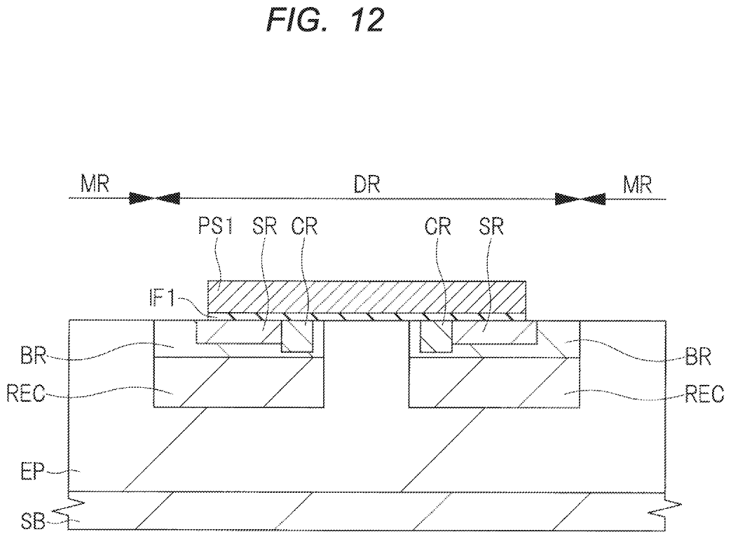

FIG. 12 shows a step of forming an insulating film IF1 and a polysilicon film PS1.

First, an insulating film IF1 formed of, for example, a silicon oxide film and having a thickness of, for example, 20 nm is formed on the epitaxial layer EP by, for example, CVD. Next, a polysilicon film PS1 having a thickness of, for example, 100 nm is formed on the insulating film IF1 by, for example, CVD. As a material for constituting the polycrystalline silicon film PS1, it is preferable to use silicon, which is a semiconductor that oxidizes faster than SiC.

Next, a resist pattern is formed to selectively cover a portion of the polysilicon film PS1. Next, dry etching is performed using the resist pattern as a mask to remove the polysilicon film PS1 exposed from the resist pattern. At this time, the insulating film IF1 functions as an etching stopper film. Next, the resist pattern is removed by asking or the like. Next, wet etching is performed using the polycrystalline silicon film PS1 as a mask to remove the insulating film IF1 not covered with the polycrystalline silicon film PS1, thereby exposing a portion of the source regions SR, a portion of the epitaxial layer EP, and the body regions BR formed therebetween. The exposed body regions BR becomes a MISFET channel region.

Since the insulating film IF1 is removed by wet etching instead of dry etching, an upper surface of the body regions BR becoming as a channel region can be prevented from being damaged. As a result, it is possible to suppress deterioration in performance such as an increase in an off-state current of the MISFET.

In the wet etching, an alignment accuracy of the patterning is relatively low. That is, when a mask pattern is formed on an upper portion of a film to be etched and wet etching is performed using the mask pattern as a mask, an end portion of the film tends to recede inward from the end portion of the mask pattern. And, there is a problem that it is difficult to control the receding amount.

On the other hand, in the first embodiment, first, the polysilicon film PS1 is processed with high accuracy by dry etching, and then, the insulating film IF1 is processed by wet etching. Since the thickness of the insulating film IF1 below the polysilicon film PS1 is about 20 nm and is relatively thin, it is possible to shorten the time of the wet etching for opening the insulating film IF1. Therefore, since the recess amount of the film to be etched by the wet etching can be minimized, the processing accuracy by the wet etching can be enhanced. As a result, the width of the MISFET in the channel length direction can be reduced, thereby it is possible to achieve high integration of the MISFET.

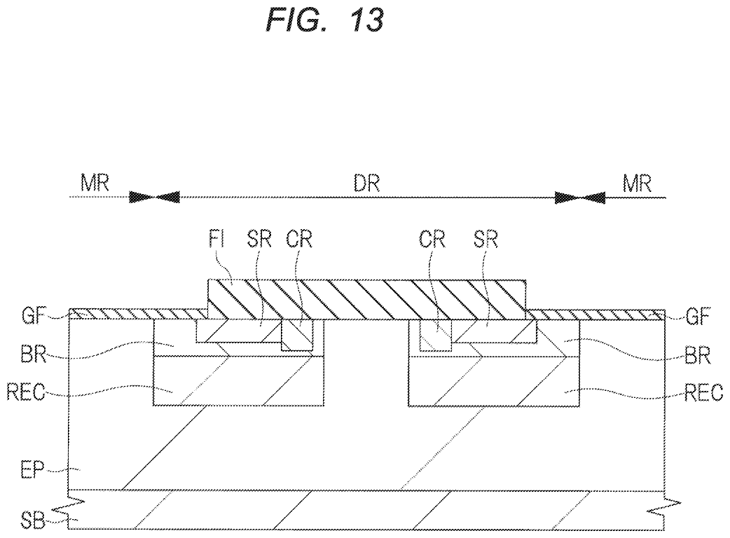

FIG. 13 shows a step of forming a gate dielectric film GF and a field insulating film FI.

First, a thermal oxidation treatment performs to the epitaxial layer EP and the polycrystalline silicon film PS1, whereby a gate dielectric film GF formed of a silicon oxide film and having a thickness of, for example, 50 nm is formed on an upper surface of each of the source regions SR exposed from the insulating film IF1, the body regions BR, and the epitaxial layer EP. At this time, the polycrystalline silicon film PS1 is also oxidized, and the entire of the polycrystalline silicon film PS1 becomes a silicon oxide film. Wherein, a laminated film of a silicon oxide film in which the polycrystalline silicon film PS1 is oxidized and an insulating film IF1 existing below the polycrystalline silicon film PS1 is illustrated as a field-insulating film FI. The thickness of the field insulating film FI is, for example, 250 nm.

Each of the field insulating film FI1 and the gate dielectric film GF are formed of a silicon oxide film and are connected to each other to be integrated, but since a portion where the gate dielectric film GF is formed functions substantially as a gate dielectric film of the MISFET, these are distinguished here.

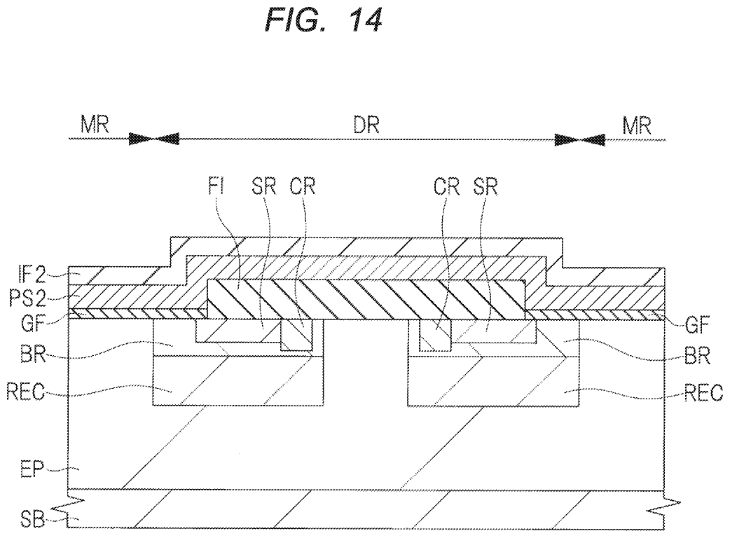

FIG. 14 shows a step of forming a polysilicon film PS2 and an insulating film IF2.

First, an n-type polysilicon film PS2 having a thickness of, for example, 200 nm is formed on the gate dielectric film GF and the field insulating film FI by, for example, CVD. Next, an insulating film IF2 formed of, for example, a silicon nitride film and having a thickness of, for example, 150 nm is formed on the polycrystalline silicon film PS2 by, for example, CVD.

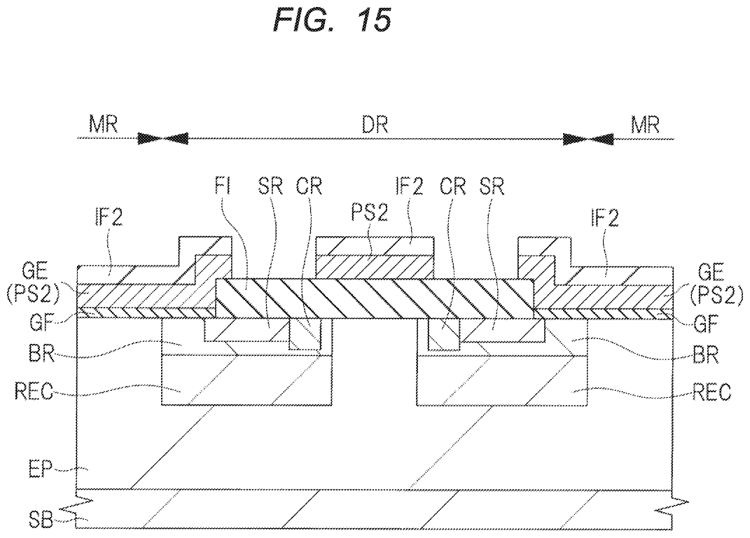

FIG. 15 shows a step of forming a gate electrode GE.

A portion of the insulating film IF2 located above the source regions SR and the contact regions CR are selectively removed by using photolithography and anisotropic etching. Next, anisotropic etching is performed using the processed insulating film IF2 as a mask, whereby the polysilicon film PS2 is patterned to form a gate electrode GE. An end portion of the gate electrode GE is located on the field insulating film FI. The gate dielectric film GF, the gate electrode GE, and the insulating film IF2 are located on an upper surface of the body regions BR becoming as a channel region.

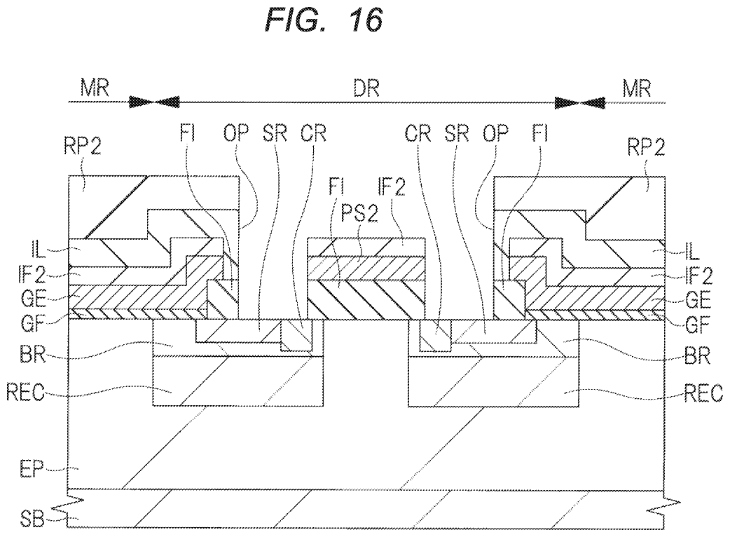

FIG. 16 shows a step of forming an interlayer insulating film IL.

First, an interlayer insulating film IL formed of, for example, a silicon oxide film and having a thickness of, for example, 250 nm is formed on the field insulating film FI and the insulating film IF2 by, for example, CVD. Next, a resist pattern RP2 for opening the epitaxial layer EP between the source regions SR, the contact regions CR, and the two body regions BR is formed. Next, the interlayer insulating film IL and the field insulating film FI are removed by anisotropic etching using the resist pattern RP2 as a mask, thereby forming an opening OP in the interlayer insulating film IL.

As a result, the source regions SR and the contact regions CR are exposed in the opening OP, and the epitaxial layer EP between the two body regions BR is covered with the remaining field insulating film FI, the polysilicon film PS2, and the insulating film IF2. That is, the region where the SBD is formed is covered with the field insulating film FI, the polysilicon film PS2, and the insulating film IF2. Thereafter, the resist pattern RP2 is removed by asking or the like.

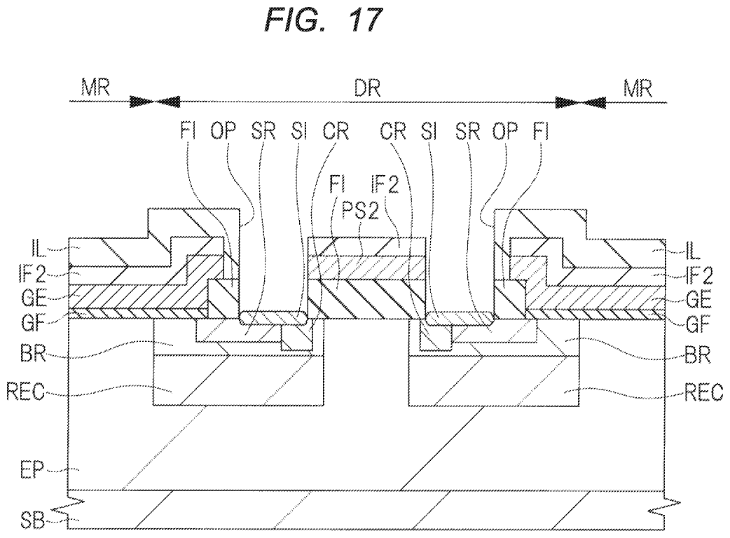

FIG. 17 shows a step of forming a silicide layer SI.

A low resistance silicide layer SI1 is formed on the source regions SR and the contact regions CR by Salicide (Self Aligned Silicide) technology. Specifically, the silicide layer SI1 can be formed as follows. First, a metal film for forming the silicide layer SI1 is formed on the source regions SR and the contact regions CR in the opening OP. The metal film is made of, for example, nickel. Next, a heat treatment is performed at about 600 to 700° C., whereby the material contained in the source regions SR and the contact regions CR and the metal film are reacted with each other. As the result, the silicide layer SI1 made of nickel silicide (NiSi) is formed on the source regions SR and the contact regions CR. Thereafter, the unreacted metal film is removed.

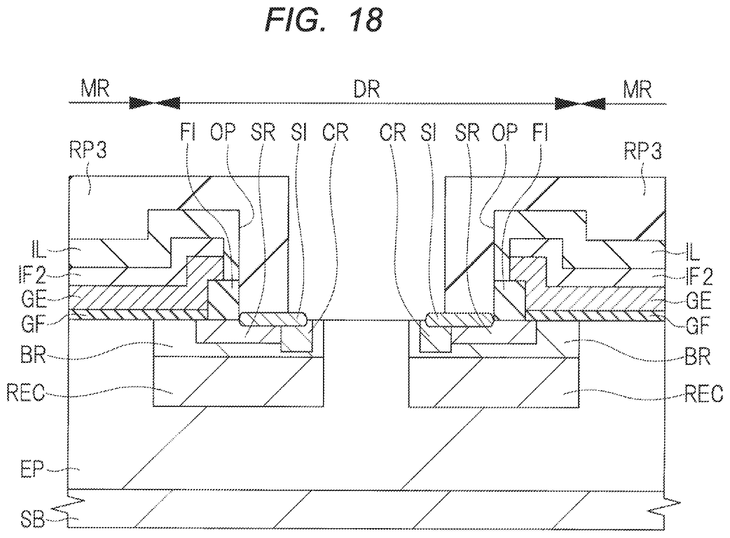

FIG. 18 shows a step of removing the field insulating film FI, the polysilicon film PS2, and the insulating film IF2 left in the opening OP.

First, in the opening OP, a resist pattern RP3 for opening the epitaxial layer EP between the two body regions BR is formed. Next, wet etching is performed using the resist pattern RP3 as a mask, whereby the field insulating film FI, the polysilicon film PS2, and the insulating film IF2 in the opening OP are sequentially removed. Thereafter, the resist pattern RP3 is removed by asking or the like.

Wherein, since the wet etching is used instead of the dry etching, it is possible to prevent an upper surface of the epitaxial layer EP for performing Schottky-connection of SBD from being damaged and an upper surface of the epitaxial layer EP from being roughened.

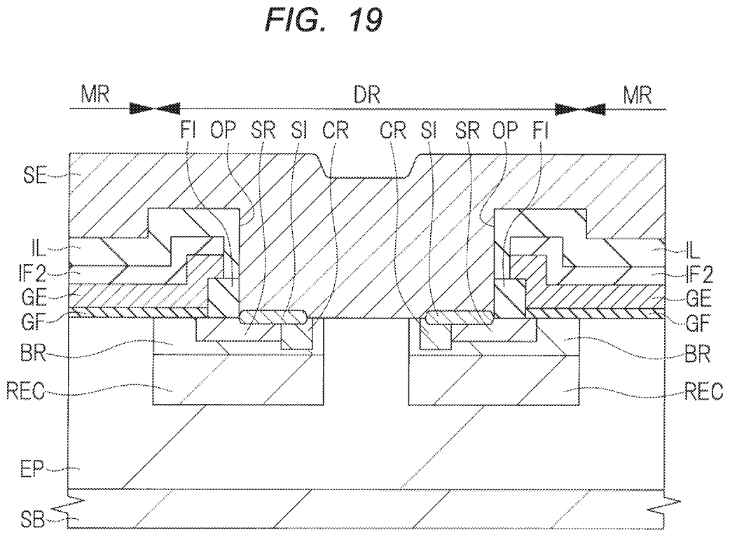

FIG. 19 shows a step of forming a source electrode SE.

First, a barrier metal film is formed on the interlayer insulating film IL by, for example, a sputtering method so as to fill the opening OP, and a conductive film is formed on the barrier metal film, thereby forming a source electrode SE having the barrier metal film and the conductive film. The barrier metal film is, for example, a titanium film or a titanium nitride film, or a laminated film in which a titanium nitride film is formed on the titanium film, and the conductive film is, for example, an aluminum film.

In the opening OP, the source electrode SE is connected to the source regions SR via the silicide layer SI and is connected to the body regions BR via the contact regions CR and the silicide layer SI. Thus, the source electrode SE is ohmic connected to the source regions SR and the contact regions CR.

In the opening OP, a region of the epitaxial layer EP, in which the body regions BR are not formed is directly connected to the source electrode SE, and the source electrode SE and the epitaxial layer EP are Schottky-connected. That is, the SBD is formed in the opening OP.

Thereafter, a drain electrode DE is formed on the back surface of the semiconductor substrate SB by, for example, a sputtering method, and the drain electrode DE is formed of, for example, a stack conductive film of an aluminum film and a gold film, thereby obtaining the structure shown in FIG. 1.

Prior to forming the drain electrode DE, nitrogen ions may be implanted into the back surface of the semiconductor substrate SB to form n-type impurity regions having higher impurity concentrations than the semiconductor substrate SB. In addition, a nickel film may be deposited between the back surface of the semiconductor substrate SB and the drain electrode DE, and a laser annealing treatment may be performed on the nickel film to form the silicide layer made of nickel silicide. Wherein, the reason why the heating is performed by the laser annealing process is to prevent the element formed on the epitaxial layer EP from being overheated.

As described above, the semiconductor device of the first embodiment is manufactured.

### Second Embodiment

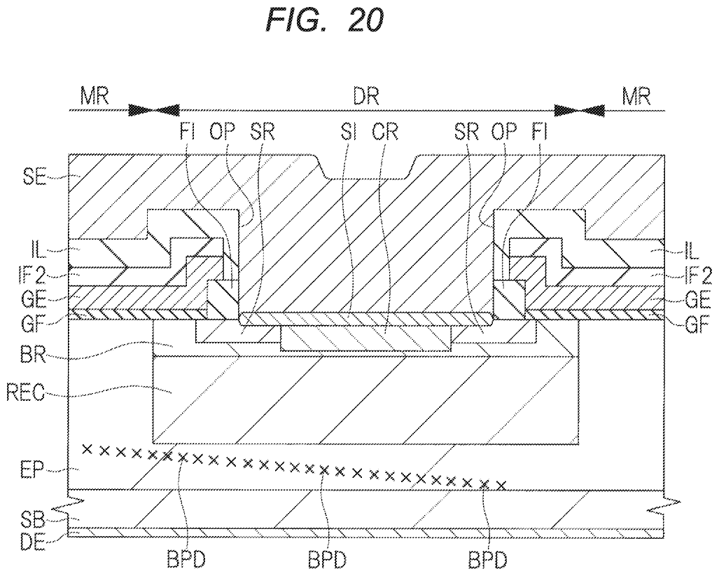

A semiconductor device of a second embodiment will be described below with reference to FIG. 20. In the following explanation, differences from the first embodiment will be mainly explained.

In the first embodiment, the SBD is formed in the opening OP, but in the second embodiment, the SBD is not formed in the opening OP, and the body region BR is formed entirely in the opening OP, and instead of forming the SBD, the area of the pn-type diode is increased. That is, the body region BR is formed to include the opening OP in plan view. In other words, the body region BR is formed directly under the opening OP via the source regions SR and the contact region CR. In the opening OP, a silicide layer SI is formed on the two source regions SR and on the contact region CR sandwiched between the two source regions SR. Therefore, the source regions SR and the body region BR are electrically connected to the source electrode SE via the silicide layer SI.

In the second embodiment, similarly to first embodiment, the recombination layer REC is formed below the body region BR. Therefore, during the operation of the pn-type diode which is the body diode, holes injected from the body region BR recombine in the recombination layer REC, so that the hole concentration in the drift layer does not increase. Therefore, the recombination of holes in the BPD can be suppressed, and the increase of stacking defects in the BPD can be suppressed.

In addition, compared with the first embodiment, since SBD is not embedded in semiconductor chip, unit cell can be reduced and on-resistance per unit area can be reduced. Alternatively, the chip area can be reduced by comparison with the same on-resistance.

FIG. 6 is a graph illustrated the results calculated by the inventors. FIG. 6 differs from FIG. 5 in that there is no SBD, but similarly to FIG. 5, shows a relationship between the hole concentration injected into the recombination layer REC and the thickness of the recombination layer REC.

Since the second embodiment does not have SBD and has only the pn-type diode, the hole current is tripled even at the same current values. FIG. 6 shows a depth distributions of hole concentrations when a hole current of 210 A/cm² flows into the recombination layer REC using the hole recombination speed as a parameter. Therefore, by inserting the recombination layer REC having a hole recombination speed of 10 nsec into the epitaxial layer EP above the BPD and setting the thickness of the recombination layer REC to 3.4 μm or more, the hole concentration passing through the recombination layer REC is reduced to 1×10¹⁶/cm³ or less.

<A Method of Manufacturing the Semiconductor Device of the Second Embodiment>

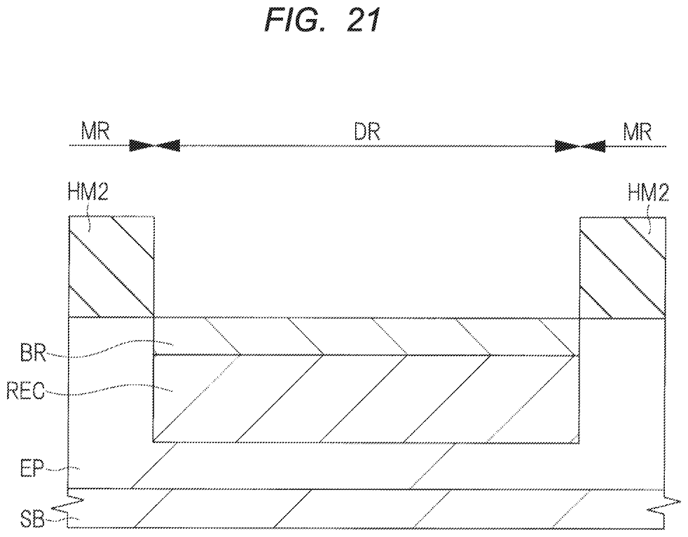

A method of manufacturing the semiconductor device of the second embodiment will be described below with reference to FIGS. 21 to 31. The method of manufacturing the second embodiment is the same as the method of manufacturing the first embodiment up to the step of FIG. 7 described in the first embodiment.

FIG. 21 shows a manufacturing step subsequent to FIG. 7, and shows a step of forming a plurality of a hard mask HM2, a body region BR, and a recombination layer REC.

First, an insulating film made of the same materials as the plurality of the hard mask HM1 of the first embodiment is formed on the epitaxial layer EP by, for example, CVD. Next, an insulating film is patterned by photolithography technology and etching process to selectively form a plurality of a hard mask HM2 on the epitaxial layer EP. Next, aluminum ions are implanted using the plurality of the hard mask HM2 as mask to form p-type body region BR in the epitaxial layer EP. Wherein, the plurality of the hard mask HM2 are left without being removed.

Next, using the plurality of the hard mask HM2 as mask, for example, hydrogen (H) ions are implanted to form recombination layer REC under the body region BR. The ion implantation is performed in a plurality of times, an acceleration energy is 100 to 400 keV, and a total dose is 2×10¹⁶/cm². In the second embodiment, a thickness of the recombination layer REC is between 3.4 and 5.0 μm. The recombination layer REC may be provided between the body region BR and the BPD and may be in contact with the body region BR or may be separated from the body region BR. Note that helium (He) can be used instead of hydrogen in the second embodiment as well.

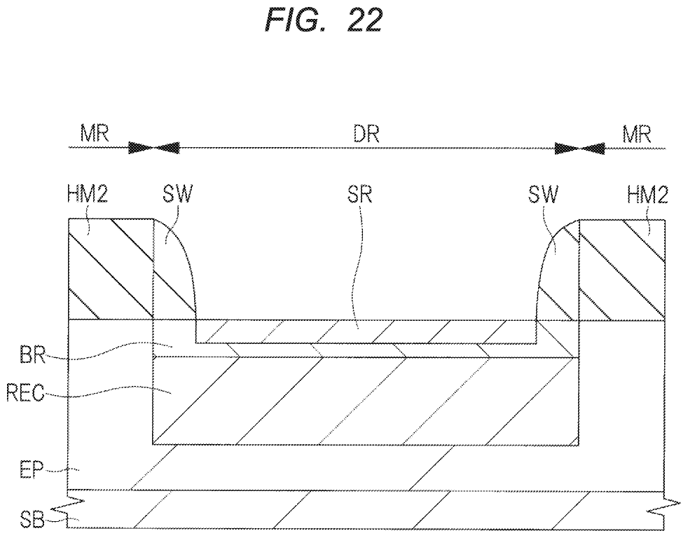

FIG. 22 shows a step of forming sidewall spacers SW and source regions SR.

First, sidewall spacers SW are formed on the side surface of the plurality of the hard mask HM2 by a method similar to the first embodiment.

Next, for example, nitrogen ions are implanted using the plurality of the hard mask HM2 and the sidewall spacers SW formed on the side surfaces of the plurality the hard mask HM2 as mask to form n-type source regions SR in the body region BR. The source regions SR are formed in a central portion of the body region BR and is formed so as to be included in the body region BR in plan view. Thereafter, a wet etching is used to remove the plurality of the hard mask HM2 and the sidewall spacers SW formed on the side surfaces of the hard mask HM2.

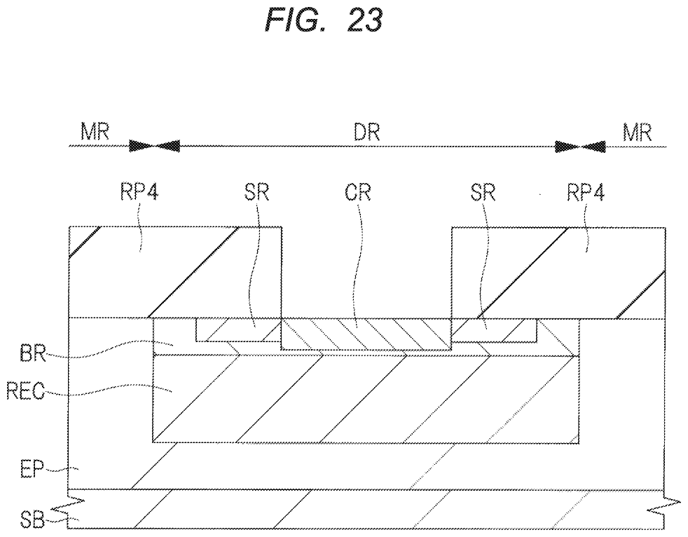

FIG. 23 shows a step of forming a contact region CR.

First, a resist pattern RP4 is formed to selectively open a portion of the body region BR. Next, aluminum ions are implanted using the resist pattern RP4 as a mask to form a p-type contact region CR in the body region BR. The contact region CR is formed at a position in contact with the source regions SR so as to be included in the body region BR in plan view. Thereafter, the resist pattern RP4 is removed by ashing or the like.

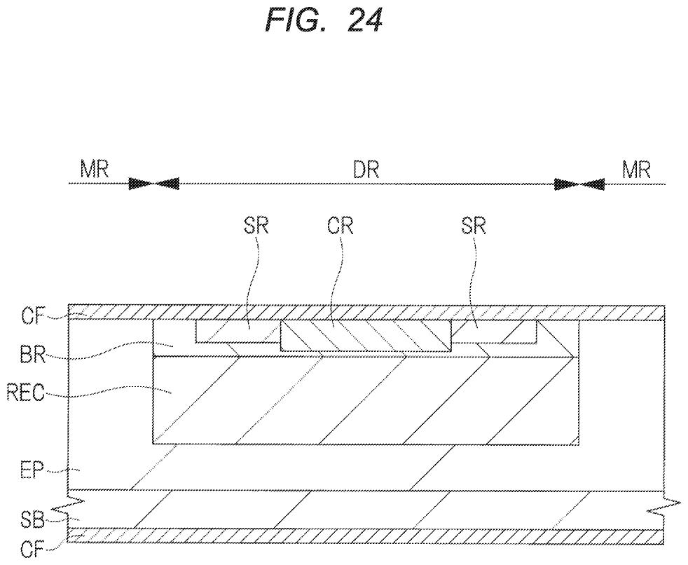

FIG. 24 shows a heat treatment step for each impurity region.

First, a carbon film CF is formed by a method similar to the first embodiment. Next, the epitaxial layer EP and the semiconductor substrate SB are performed to heat treatment at, for example, 1700 to 1800° C. to activate impurities included in the semiconductor substrate SB, the epitaxial layer EP, the body region BR, the source regions SR, and the contact region CR. Thereafter, the carbon film CF is removed.

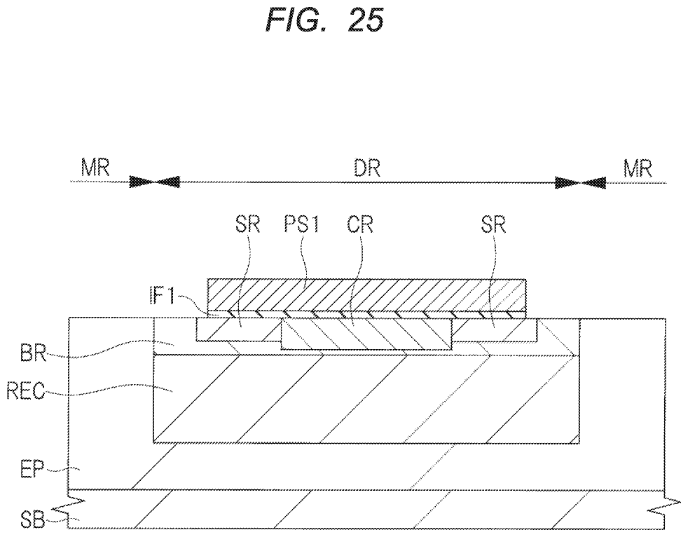

FIG. 25 shows a step of forming an insulating film IF1 and a polysilicon film PS1.

First, an insulating film IF1 is formed on the epitaxial layer EP and a polysilicon film PS1 is formed on the insulating film IF1 by a method similar to the first embodiment.

Next, a resist pattern is formed to selectively cover a portion of the polysilicon film PS1. Next, dry etching is performed using the resist pattern as a mask to remove the polysilicon film PS1 exposed from the resist pattern. Next, the resist pattern is removed by ashing or the like. Next, wet etching is performed using the polycrystalline silicon film PS1 as a mask to remove the insulating film IF1 not covered with the polycrystalline silicon film PS1, thereby a portion of the source regions SR, a portion of the epitaxial layer EP, and the body region BR formed therebetween are exposed. The exposed body region BR becomes as a MISFET channel region.

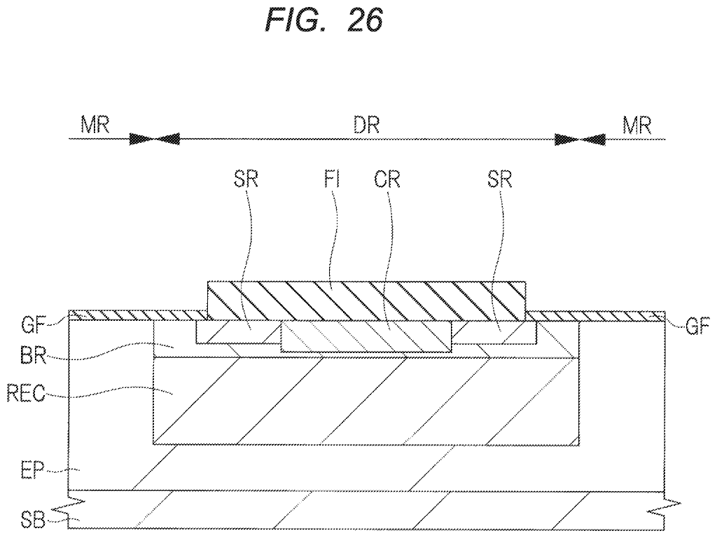

FIG. 26 shows a step of forming a gate dielectric film GF and a field-insulating film FI.

First, by performing a thermal oxidization process similar to the first embodiment, a gate dielectric film GF is formed on an upper surface of each of the source regions SR, the body region BR, and the epitaxial layer EP exposed from the insulating film IF1. At this time, the polycrystalline silicon film PS1 is also oxidized, and the entire of the polycrystalline silicon film PS1 becomes a silicon oxide film. As a result, a field insulating film FI is formed of a laminated film of a silicon oxide film in which the polycrystalline silicon film PS1 is oxidized and the insulating film IF1 existing below the polycrystalline silicon film PS1.

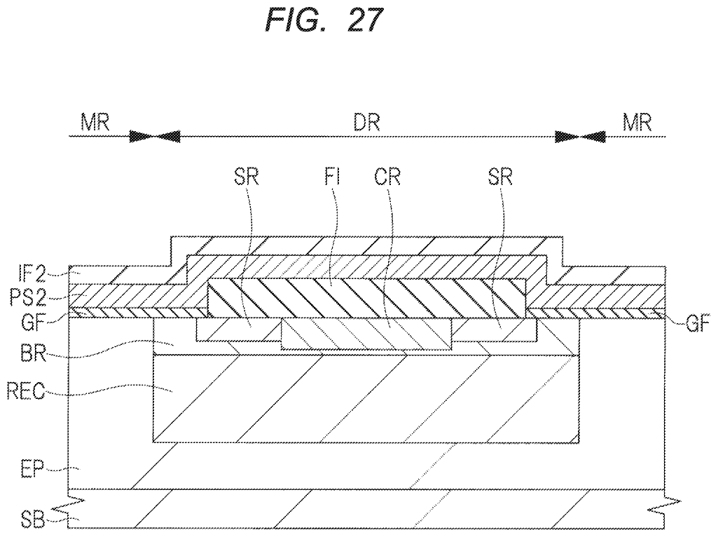

FIG. 27 shows a step of forming a polysilicon film PS2 and an insulating film IF2.

A polycrystalline silicon film PS2 is formed on the gate dielectric film GF and the field insulating film FI by the same method as the first embodiment, and an insulating film IF2 is formed on the polycrystalline silicon film PS2.

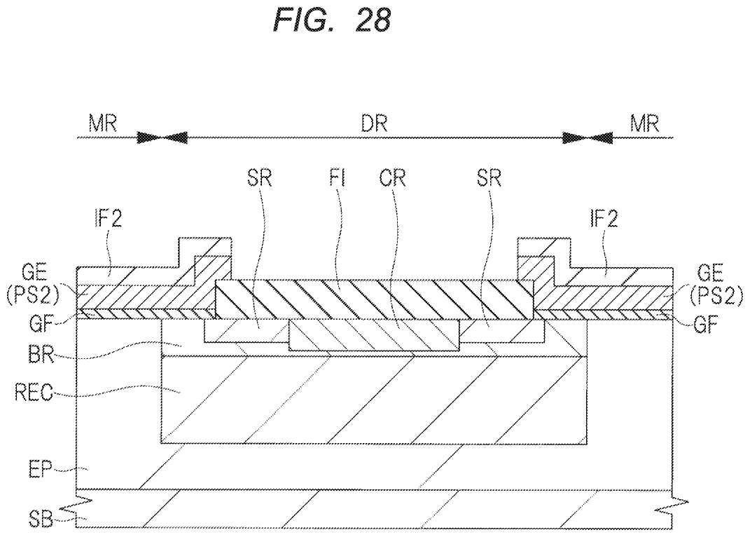

FIG. 28 shows a step of forming a gate electrode GE.

First, a portion of the insulating film IF2 is selectively removed by a method similar to the first embodiment. Next, anisotropic etching is performed using the processed insulating film IF2 as a mask, whereby the polysilicon film PS2 is patterned to form gate electrode GE.

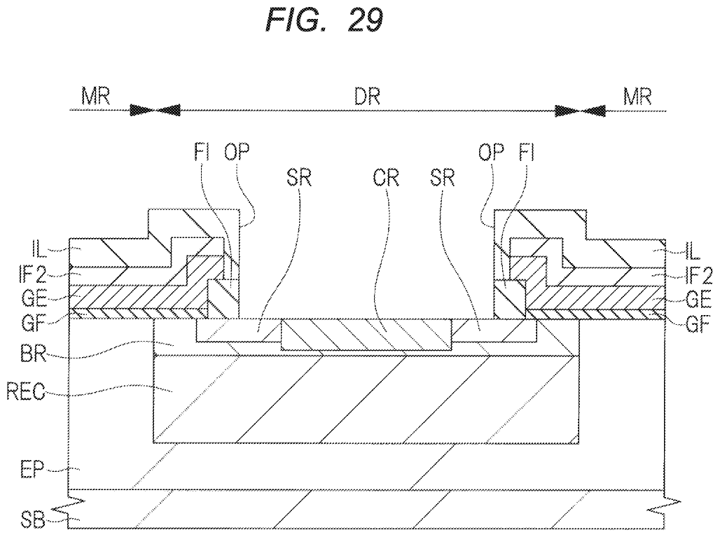

FIG. 29 shows a step of forming an interlayer insulating film IL.

First, the interlayer insulating film IL is formed by a method similar to the first embodiment. Next, an opening OP is formed in the interlayer insulating film IL by photolithography technology and anisotropic etching so as to expose the source regions SR and the contact region CR.

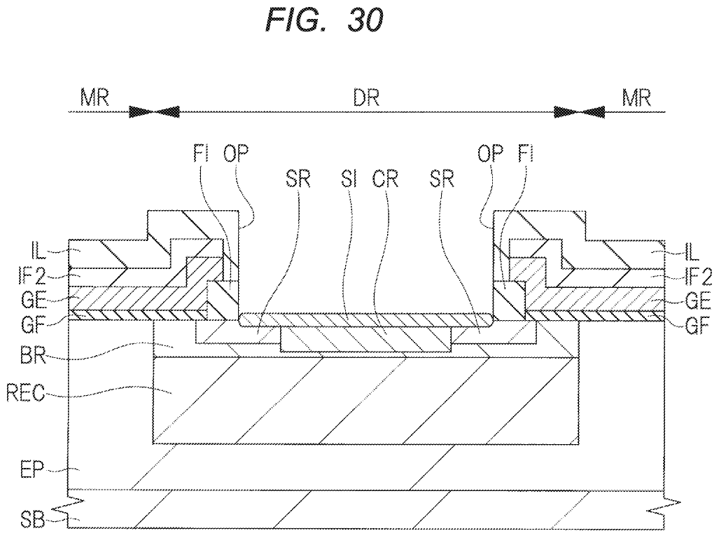

FIG. 30 shows a step of forming a silicide layer SI.

A low resistance silicide layer SI1 is formed on the source regions SR and the contact region CR by a method similar to the first embodiment. In the second embodiment, unlike the first embodiment, a silicide layer SI are formed on an entire of bottom portion of the opening OP.

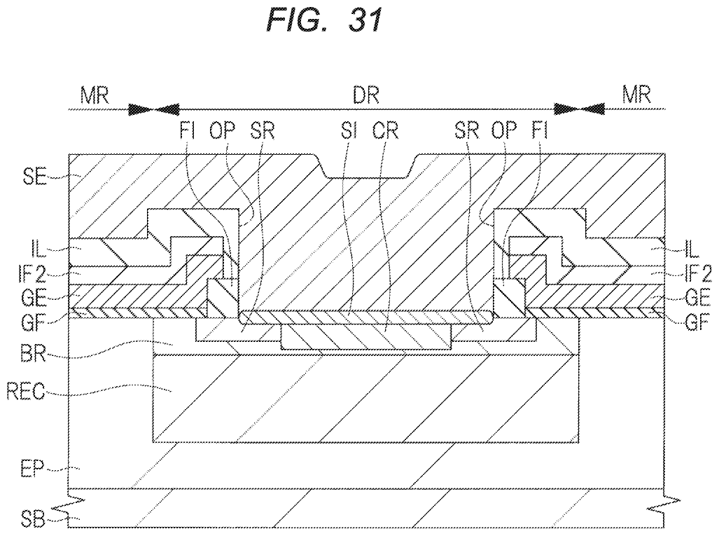

FIG. 31 shows the step of forming a source electrode SE.

By a method similar to the first embodiment, a source electrode SE is formed on the interlayer insulating film IL so as to embedded in the opening OP. In the opening OP, the source electrode SE is connected to the source regions SR via the silicide layer SI and is connected to the body region BR via the contact region CR and the silicide layer SI. Thus, the source electrode SE is ohmic connected to the source regions SR and the contact region CR.

Thereafter, a drain electrode DE is formed on the back surface of the semiconductor substrate electrode DE by a method similar to the first embodiment, whereby the structure shown in FIG. 20 is obtained.

### Third Embodiment

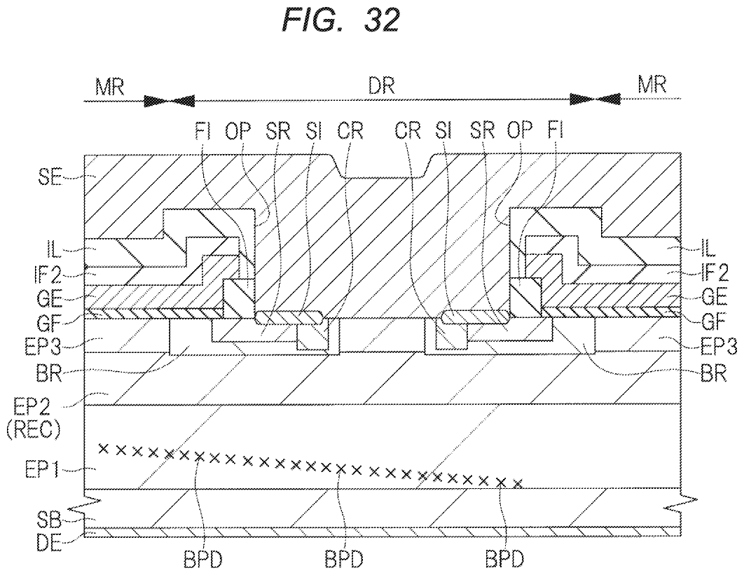

A semiconductor device of a third embodiment will be described below with reference to FIG. 32. In the following explanation, differences from the first embodiment will be mainly explained.

In the first embodiment, a single epitaxial layer EP is formed as a drift layer on the semiconductor substrate SB, a body region BR is formed in the epitaxial layer EP, and then a recombination layer REC is formed by, for example, ion implantation of hydrogen into the epitaxial layer EP under the body region BR. In the third embodiment, a three-layers of epitaxial layer EP1-EP3 is formed as a drift layer, and an epitaxial layer EP2 constitutes the recombination layer REC.

Specifically, in the first embodiment, the recombination layer REC is formed by finally forming point defects in the hydrogen-implanted region and increasing the point defect density. The recombination layer REC of the third embodiment is formed by adding a metal such as iron or nickel as an impurity instead of increasing the point defect density, and the epitaxial layer EP2 itself to which such a metal is added forms the recombination layer REC.

For example, in case of the metal is iron, iron in a SiC forms a deep energy level at a position away from a valence band and a conduction band, and it constitutes a recombination center. That is, when electrons and holes are injected into the energy level, they recombine. In addition, since a metal such as iron is difficult to diffuse due to heat in each manufacturing steps, the added metal finally remains in the recombination layer REC.

The epitaxial layer EP1 has an impurity concentration of, for example, 1×10¹⁶/cm³ and a thickness of, for example, 8 to 10 μm. The BPD are existed in the epitaxial layer EP1. The metal doped epitaxial layer EP2 has an impurity concentration of, for example, 1×10¹⁷/cm³ and a thickness of, for example, 1.5 to 2.0 μm. The epitaxial layer EP3 has an impurity concentration higher than that of the epitaxial layer EP1, has an impurity concentration of, for example, 1×10¹⁷/cm³, and has a thickness of, for example, 0.3 to 0.4 μm.

The body region BR is formed in the epitaxial layer EP3 and have a thickness of, for example, 0.3 to 0.4 μm. The lower surface of the body regions BR may be located in the epitaxial layer EP3 or in the epitaxial layer EP2. Further, also in the third embodiment, similarly to the first embodiment, a source electrode SE is directly formed in the region where the body region BR is not formed in the epitaxial layer EP3, whereby the SBD is formed.

As described above, even in the third embodiment, by using the recombination layer REC (the epitaxial layer EP2), holes injected from the body region BR is combined with electrons in the recombination layer REC during the operation of the pn-type diode, it is possible to suppress an increase in a stacking defects in the BPD.

<A Method of Manufacturing the Semiconductor Device According to the Third Embodiment>

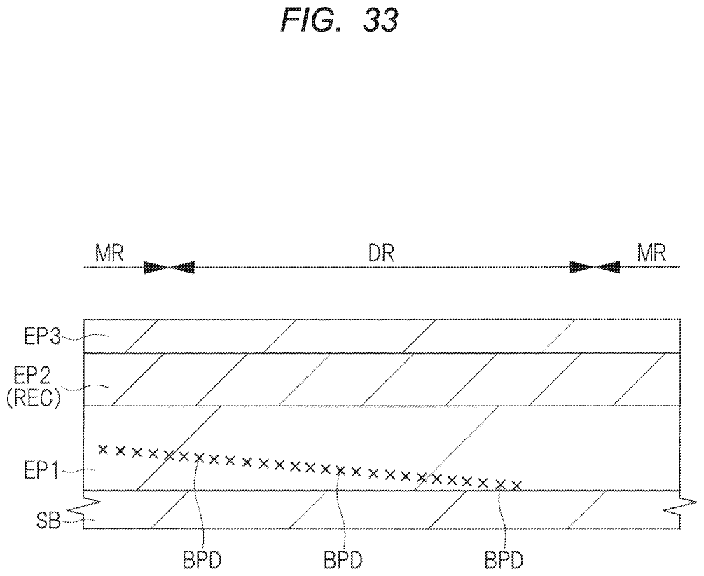

A method of manufacturing the semiconductor device according to the third embodiment will be described below with reference to FIG. 33. In the third embodiment, an epitaxial layer EP1 is formed on a semiconductor substrate SB using an epitaxial growth method similar to the first embodiment, an epitaxial layer EP2 is formed on the epitaxial layer EP1 using an epitaxial growth method, and an epitaxial layer EP3 is formed on the epitaxial layer EP2 using an epitaxial growth method.

After that, although each structure such as the body region BR and the source regions SR are formed, these manufacturing methods are substantially the same as the first embodiment, and then, a description of their manufacturing method is omitted.

The semiconductor device of the second embodiment can also be manufactured by using a three-layer epitaxial layer EP1-EP3 such as the third embodiment. In that case, a thickness of the epitaxial layer EP2 is thicker than that of the third embodiment layer, for example, 3.4 to 5.0 μm.

Although the invention made by the inventor of the present application has been specifically described based on the embodiment, the present invention is not limited to the above embodiment, and various modifications can be made without departing from the gist thereof.

For example, although the SBD is exemplified in the above embodiment, JBS (Junction Barrier Schottky) diode may be used instead of the SBD. The JBS diode is a kind of the SBD, and has a structure in which a plurality of p-type impurity regions is arranged apart from each other in an n-type epitaxial layer EP Schottky-connected to a source electrode SE.

What is claimed is:

1. A semiconductor device, comprising:
a semiconductor substrate of a first conductivity type made of silicon carbide and having an upper surface and a back surface opposite to the upper surface,
a semiconductor layer of the first conductivity type formed on the upper surface of the semiconductor substrate,
a first impurity region of a second conductivity type opposite to the first conductivity type formed in the semiconductor layer,
a second impurity region of the first conductivity type formed in the first impurity region and having a higher impurity concentration than that of the semiconductor layer,
a gate electrode formed via a gate insulating film on the first impurity region between the second impurity region and the semiconductor layer,
an interlayer insulating film formed so as to cover the gate electrode and having an opening for opening a portion of the first impurity region and a portion of the second impurity region,
a source electrode formed on the interlayer insulating film and electrically connected to the first impurity region and the second impurity region in the opening, and
a drain electrode formed on the back surface of the semiconductor substrate, wherein
a recombination layer is formed in the semiconductor layer under the first impurity region, and
the recombination layer is a layer in which a point defect density is higher than that of the semiconductor layer located directly under the recombination layer, or in which a metal is added to the semiconductor layer.

2. The semiconductor device according to claim 1, wherein
the first conductivity type is n-type,
the second conductivity type is p-type,
the first impurity region and the semiconducting layer constitute a pn-type diode, and
when the pn-type diode is operated, holes flowing from the first impurity region and electrons flowing from the semiconductor substrate are combined in the recombination layer.

3. The semiconductor device according to claim 2, wherein
a basal plane dislocation is existed in the semiconducting layer below the recombination layer.

4. The semiconductor device according to claim 3, wherein
a thickness of the recombination layer is 1.5 μm or more.

5. The semiconductor device according to claim 1, wherein
the opening opens in a region of the semiconductor layer, in which the first impurity region is not formed, and
the source electrode is connected to the semiconductor layer in the opening.

6. The semiconductor device according to claim 5, wherein
a silicide layer is formed on the first impurity region and the second impurity region in the opening,
the source electrode is connected to the first impurity region and the second impurity region via the silicide layer in the opening, and
the source electrode is directly connected to the semiconductor layer.

7. The semiconductor device according to claim 6, wherein
the source electrode has a barrier metal film and a conductive film formed on the barrier metal film, and
the barrier metal film is a titanium film, a titanium nitride film or a laminated film in which the titanium nitride film is formed on the titanium film.

8. The semiconductor device according to claim 1, wherein
the first impurity region is formed so as to include the opening in plan view.

9. The semiconductor device according to claim 1, wherein
the semiconductor layer includes:
a first semiconductor layer of the first conductivity type formed on the semiconductor substrate;
a second semiconductor layer of the first conductivity type formed on the first semiconductor layer; and
a third semiconductor layer of the first conductivity type formed on the second semiconductor layer, wherein
the first impurity region is formed in the third semiconductor layer,
the second impurity region has a higher impurity concentration than that of the first semiconductor layer, and
the recombination layer is a layer in which the second semiconductor layer is doped with the metal.

10. A method of manufacturing a semiconductor device, comprising the steps of:
(a) preparing a semiconductor substrate of a first conductivity type made of silicon carbide and having a semiconductor layer of the first conductivity type formed on an upper surface of the semiconductor substrate;
(b) forming a first impurity region of the second conductivity type opposite to the first conductivity type in the semiconductor layer;
(c) forming a recombination layer in the semiconductor layer below the first impurity region;
(d) forming a second impurity region of the first conductivity type having an impurity concentration higher than that of the semiconductor layer in the first impurity region;
(e) after the step of (d), forming a gate insulating film on the first impurity region between the second impurity region and the semiconductor layer;
(f) forming a gate electrode on the gate insulating film;
(g) forming an interlayer insulating film so as to cover the gate electrode;
(h) forming an opening for opening a portion of the first impurity region and a portion of the second impurity region in the interlayer insulating film;
(i) forming a source electrode on the interlayer insulating film so as to electrically connect to the first impurity region and the second impurity region in the opening, and
(j) forming a drain electrode on a back surface opposite to the upper surface in the semiconductor substrate, wherein
the recombination layer has a point defect density higher than that of the semiconductor layer located directly under the recombination layer.

11. The method of manufacturing a semiconductor device according to the claim 10, wherein
in the step of (b), the first impurity region is formed by ion implantation using a first mask,
in the step of (c), the recombination layer is formed by ion implantation using the first mask, and
the first mask is removed between the steps of (c) and (d).

12. The method of manufacturing a semiconductor device according to the claim 11, wherein
in the step of (c), hydrogen or helium is used for the ion implantation.

13. The method of manufacturing a semiconductor device according to the claim 12, wherein
the semiconductor layer is formed on the semiconductor substrate by an epitaxial growth method, and
a base plane dislocation is existed in the semiconducting layer below the recombination layer.

14. The method of manufacturing a semiconductor device according to the claim 13, wherein
a thickness of the recombination layers is 1.5 μm or more.

15. The method of manufacturing a semiconductor device according to the claim 10, further comprising the step of:
(k) between the steps of (h) and (i), a silicide layer is formed on the first impurity region and the second impurity region in the opening, wherein
the opening opens in a region of the semiconductor layer, in which the first impurity region is not formed,
the source electrode is connected to the first impurity region and the second impurity region via the silicide layer in the opening, and
the source electrode is directly connected to the semiconductor layer.

16. The method of manufacturing a semiconductor device according to the claim 15, wherein
the source electrode has a barrier metal film and a conductive film formed on the barrier metal film,
the barrier metal film is a titanium film, a titanium nitride film or a laminated film in which the titanium nitride film is formed on the titanium film.

17. The method of manufacturing a semiconductor device according to the claim 10, wherein
in the step of (h), the opening is formed so as to include in the first impurity region in plan view.

18. A method of manufacturing a semiconductor device, comprising the steps of:
(a) preparing a semiconductor substrate of a first conductivity type made of silicon carbide and having an upper surface and a back surface opposite to the upper surface;
(b) forming a first semiconductor layer of the first conductivity type on the upper surface of the semiconductor substrate by an epitaxial growth method;
(c) forming a second semiconductor layer of the first conductivity type doped with a metal on the first semiconductor layer by an epitaxial growth method;
(d) forming a third semiconductor layer of the first conductivity type on the second semiconductor layer by an epitaxial growth method;
(e) forming a first impurity region of a second conductivity type opposite to the first conductivity type in the third semiconductor layer;
(f) forming a second impurity region of the first conductivity type having an impurity concentration higher than that of the first semiconductor layer in the first impurity region;
(g) after the step of (f), forming a gate insulating film on the first impurity region between the second impurity region and the third impurity region;
(h) forming a gate electrode on the gate insulating film;
(i) forming an interlayer insulating film so as to cover the gate electrode;
(j) forming an opening for opening a portion of the first impurity region and a portion of the second impurity region in the interlayer insulating film;
(k) forming a source electrode on the interlayer insulating film so as to electrically connect to the first impurity region and the second impurity region in the opening,
(l) forming a drain electrode on the back surface of the semiconductor substrate.

19. The method of manufacturing a semiconductor device according to the claim 18, wherein
the metal is iron or nickel.

20. The method of manufacturing a semiconductor device according to the claim 18, wherein
a basal plane dislocation exists in the first semiconducting layer.
